(19) United States
(12) Patent Application Publication
(10) Pub. No.: US 2025/0280651 A1
(43) Pub. Date: Sep. 4, 2025

(54) ORGANIC LIGHT EMITTING DISPLAY DEVICE

(71) Applicant: LG Display Co., Ltd., Seoul (KR)

(72) Inventor: Dongcheol Choe, Incheon (KR)

(73) Assignee: LG Display Co., Ltd., Seoul (KR)

(21) Appl. No.: 18/999,197

(22) Filed: Dec. 23, 2024

(30) Foreign Application Priority Data
Feb. 29, 2024 (KR) 10-2024-0029835

(51) Int. Cl. H10K 50/15; H10K 50/19; H10K 59/35; H10K 101/40

(52) U.S. Cl. CPC H10K 50/15; H10K 50/19; H10K 59/35; H10K 2101/40

(57) ABSTRACT

An organic light emitting display device can include a substrate on which a red sub pixel, a blue sub pixel, a first green sub pixel and a second green sub pixel are disposed; an anode disposed separately at each of the red, blue, first green and second green sub pixels; a first hole transport layer disposed on the anode; a first auxiliary hole transport layer disposed on the first hole transport layer, at the blue sub pixel and the second green sub pixel; a first red organic emission layer, a first blue organic emission layer; a first green organic emission layer and a second green organic emission layer disposed respectively at the red, blue, first green and second green sub pixels; and a charge generation layer disposed on the red, blue, first green and second green organic emission layers.

### CROSS-REFERENCE TO RELATED APPLICATIONS

This application claims priority to Korean Patent Application No. 10-2024-0029835 filed on Feb. 29, 2024, in the Korean Intellectual Property Office, the entire disclosure of which is incorporated herein by reference into the present application.

### BACKGROUND

### Field

The present disclosure relates to an organic light emitting display device, and particularly, an organic light emitting display device that secures improvement in the emission efficiency of a green sub pixel.

### Discussion of the Related Art

Unlike a liquid crystal display device, an organic light emitting display device does not require a separate light source and can be manufactured as a lightweight thin device. Additionally, the organic light emitting display device secures excellent color manifestation, response speed, viewing angles, contrast ratios (CR) as well as consuming less power based on low-voltage driving. As such, research has been conducted into an organic light emitting display device as a next-generation display device.

The organic light emitting display device as a self-light emitting display device is a display device using an organic light emitting diode that emits light when an exciton, in which an injected electron and an injected hole are coupled, falls from an excitation state to a ground state by injecting an electron and a hole respectively from a cathode and an anode into an emission layer.

The organic light emitting display device is based on a top emission method and a bottom emission method, depending on a direction in which light generated from an organic emission layer is emitted. In the case of an organic light emitting display device based on the top emission method, light emitted from the organic emission layer is emitted upward through the cathode. In the top-emission organic light emitting display device, a greater opening ratio can be secured than in the bottom-emission organic light emitting display device, the opening ratio of which is affected by a thin film transistor disposed under the organic emission layer. Accordingly, in recent years, research into a top-emission organic light emitting display device has been conducted actively.

### SUMMARY OF THE DISCLOSURE

One objective of the present disclosure is to provide an organic light emitting display device that is provide with a first green sub pixel and a second green sub pixel having a different emission property, so that generation of an afterimage and deterioration in luminance, which can be caused by a change in viewing angles, can improve at a time of low-gradation driving.

Another objective of the present disclosure is to provide an organic light emitting display device comprising a green sub pixel that secures excellent emission efficiency and luminance properties and decrease driving voltage.

Yet another objective of the present disclosure is to provide an organic light emitting display device capable of driving green sub pixels having a different emission property at the same time without an additional manufacturing process and an additional driving method.

Objects of the present disclosure are not limited to the above-mentioned objects, and other objects, which are not mentioned above, can be clearly understood by those skilled in the art from the following descriptions.

An organic light emitting display device according to one embodiment of the present disclosure comprises a substrate on which a red sub pixel, a blue sub pixel, a first green sub pixel and a second green sub pixel are disposed; an anode disposed separately at each of the red, blue, first green and second green sub pixels; a first hole transport layer disposed on the anode; a first auxiliary hole transport layer disposed on the first hole transport layer, at the blue sub pixel and the second green sub pixel; a first red organic emission layer, a first blue organic emission layer, a first green organic emission layer and a second green organic emission layer disposed respectively at the red, blue, first green and second green sub pixels; a charge generation layer disposed on the red, blue, first green and second green organic emission layers; a second auxiliary hole transport layer disposed on the charge generation layer; a second red organic emission layer, a second blue organic emission layer, a third green organic emission layer and a fourth green organic emission layer disposed on the second auxiliary hole transport layer, at each of the red, blue, first green and second green sub pixels; an electron transport layer disposed on the second red, second blue, third green and fourth green organic emission layer; and a cathode disposed on the electron transport layer, wherein the second auxiliary hole transport layer comprises a second green auxiliary hole transport layer and a second blue auxiliary hole transport layer disposed at the second green sub pixel.

Other detailed matters of the example embodiments of the present disclosure are included in the detailed description and the drawings.

In the organic light emitting display device according to one embodiment of the present disclosure, the entire height of a light emitting diode and the optical distance of an organic emission layer can change, thereby providing two green sub pixels having a different optical property.

In the organic light emitting display device according to one embodiment of the present disclosure, an auxiliary hole transport layer or an electron blocking layer of the blue sub pixel can be additionally disposed at the green sub pixel, thereby providing an organic light emitting display device comprising a second green sub pixel securing excellent emission efficiency and luminance, and decreasing driving voltage.

In the organic light emitting display device according to one embodiment of the present disclosure, at a time of low-gradation driving, problems such as unintended emission of light or an after image can be resolved, and the emission properties of a green sub pixel can improve.

In the organic light emitting display device according to one embodiment of the present disclosure, deterioration in luminance depending on the viewing angle of a green sub pixel can improve.

The effects according to aspects of the present disclosure are not limited to the contents provided herein, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic plan view of an organic light emitting display device according to one or more embodiments of the present disclosure;

FIG. 2 is an enlarged plan view of area A of FIG. 1;

FIG. 3 is a schematic cross-sectional view of the organic light emitting display device according to one or more embodiments of the present disclosure;

FIG. 4 is a graph of current density properties based on a driving voltage of a green sub pixel of Comparative example 1 and Embodiment 1 of the present disclosure; and

FIG. 5 is a graph of emission efficiency properties based on a thickness of an auxiliary hole transport layer of a green sub pixel of Comparative example 2 and Embodiment 1 of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

Like reference numerals generally denote like elements throughout the disclosure. Further, the term “can” fully encompasses all the meanings and coverages of the term “may.”

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings. All the components of each display device according to all embodiments of the present disclosure are operatively coupled and configured.

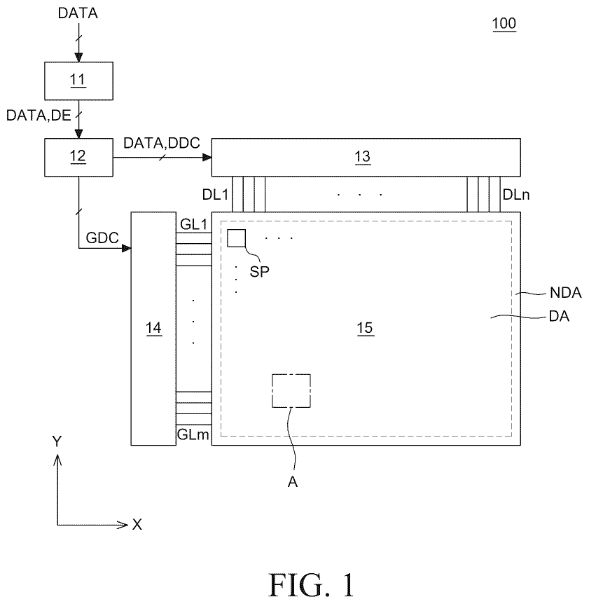

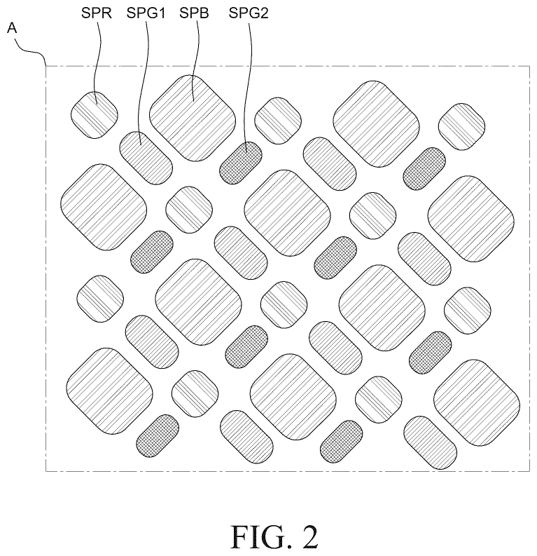

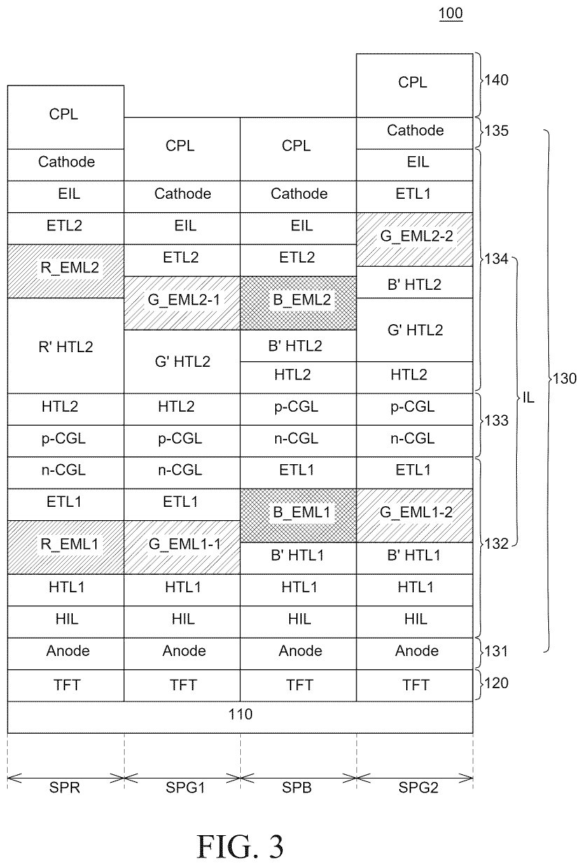

FIGS. 1-3 are views for describing an organic light emitting display device according to one or more embodiments of the present disclosure. Particularly, FIG. 1 is a schematic plan view of an organic light emitting display device according to one or more embodiments of the present disclosure. FIG. 2 is an enlarged plan view of area A of FIG. 1. FIG. 3 is a schematic cross-sectional view of the organic light emitting display device according to one or more embodiments of the present disclosure.

Referring to FIG. 1, an organic light emitting display device 100 according to one or more embodiments of the present disclosure comprises an image processor 11, a timing controller 12, a data driver 13, a scan driver 14, and a display panel 15.

The image processor 11 outputs a data enable signal DE and the like together with a data signal DATA provided from the outside. The image processor 11 can output one or more of a perpendicular synchronization signal, a horizontal synchronization signal and a clock signal, in addition to the data enable signal DE. The image processor 11 is formed into an integrated circuit (IC) on a system circuit board.

The timing controller 12 is supplied from the image processor 11 with a data signal DATA together with a data enable signal DE or a driving signal comprising a perpendicular synchronization signal, a horizontal synchronization signal, and a clock signal and the like. The timing controller 12 outputs a gate timing control signal GDC for controlling an operation timing of the scan driver 14 and a data timing control signal DDC for controlling an operation timing of the data driver 13, based on a driving signal. The timing controller 12 is formed into an IC on a control circuit board.

The data driver 13 samples and latches a data signal DATA provided from the timing controller 12 in response to a data timing control signal DDC provided from the timing controller 12, and converts the sampled and latched data signal DATA to a gamma reference voltage and outputs the same. The data driver 13 provides a data signal DATA converted through data lines DL1-DLn to sub pixels SP included in the display panel 15. The data driver 13 can be formed into an integrated circuit (IC).

The scan driver 14 generates a scan signal consecutively in response to a gate timing control signal GDC provided from the timing controller 12. The scan driver 14 provides a scan signal generated through scan lines GL1-GLm to sub pixels SP. The scan driver 14 can be formed into an IC on a gate circuit board, or based on the gate in panel (GIP) method, can be formed on the display panel 15.

The display panel 15 displays an image in response to a data signal DATA and a gate signal provided from the data driver 13 and the scan driver 14. The display panel 15 comprises a plurality of sub pixels SP displaying an image.

The organic light emitting display device 100 comprises a display area DA (or active area) and a non-display area NDA (or non-active area). The non-display area NDA can surround the display area DA entirely or only in part(s). The display area DA is an area where the plurality of sub pixels SP is disposed and an image is substantially displayed. In the display area DA, a plurality of sub pixels SP comprising an emission area for displaying an image, and a driving circuit for driving the sub pixels SP can be disposed. A sub pixel SP, as an element for displaying one color, comprises an emission area where light emits and a non-emission area where light does not emit, but in the present disclosure, the emission area where light emits is only defined as a sub pixel. The plurality of sub pixels SP is arranged in a matrix form. The non-display area NDA surrounds the display area DA. In the non-display area NDA as an area where an image is not displayed substantially, a variety of lines for driving a pixel and a driving circuit disposed in the display area DA, a driving IC, a printed circuit board and the like are disposed. For example, in the non-display area NDA, a variety of ICs such as a gate driver IC and a data driver IC, VSS lines and the like can be disposed.

The plurality of sub pixels SP can be arranged in a matrix form. The plurality of sub pixels SP can constitute one pixel unit.

For example, referring to FIG. 2, one or each pixel unit can comprise a first sub pixel, a second sub pixel, a third sub pixel and a fourth sub pixel. The first sub pixel, the second sub pixel, the third sub pixel and the fourth sub pixel can display a different color respectively, or when necessary, part of the sub pixels can display the same color. In the organic light emitting display device 100 according to one or more embodiments of the present disclosure, the first sub pixel is a red sub pixel SPR, the second sub pixel is a first green sub pixel SPG1, the third sub pixel is a blue sub pixel SPB, and the fourth sub pixel is a second green sub pixel SPG2. In FIG. 2, an area indicated by hatches is the emission area of each sub pixel, and the remaining area not indicated by hatches is a non-emission area.

At this time, the red, blue, first green and second green sub pixels SPR, SPB, SPG1, SPG2 can be arranged in a pentile structure. In the case where the red, blue, first green and second green sub pixels SPR, SPB, SPG1, SPG2 are arranged in a pentile structure, the number of the red sub pixels SPR and the blue sub pixels SPB disposed in the display area DA can be less than in the case were the red, blue, first green and second green sub pixels SPR, SPB, SPG1, SPG2 are arranged in a stripe structure. As the number of the sub pixels SP decreases, an aperture ratio can be improved while maintaining the same level of cognitive resolution compared to the stripe structure. Additionally, a decrease in the number of the sub pixels SP can lead to a simplified manufacturing process of an organic light emitting display panel and efficient power consumption.

In the pentile structure, the first green sub pixel SPG1 and the second green sub pixel SP2 can have a surface area less than that of the red sub pixel SPG and the blue sub pixel SPB, considering luminance and color temperature. For example, the red sub pixel SPR and the blue sub pixel SPB can be arranged alternately in a first direction (e.g., an X-axis direction), and the first green sub pixel SPG1 and the second green sub pixel SPG2 can be spaced from the red sub pixel SPR and the blue sub pixel SPB in a second direction (e.g., a Y-axis direction) and arranged alternately along the first direction (the X-axis direction), but not limited thereto.

In FIG. 2, the red, blue, first green and second green sub pixels SPR, SPB, SPG1, SPG2 are formed in a pentile structure, for example, but not limited thereto. The colors and disposition of the sub pixels can vary, when necessary. Additionally, in FIG. 2, each of the red, blue, first green and second green sub pixels SPR, SPB, SPG1, SPG2 can be shaped into an octagon, for example, but not limited thereto, and can have various shapes. For example, each of the sub pixels can be shaped into a polygon except for a circle, an oval or an octagon.

Each of the red, blue, first green and second green sub pixels SPR, SPB, SPG1, SPG2, as illustrated in FIG. 3, comprises a substrate 110, an organic light emitting diode 130 emitting light, a thin film transistor 120 for transferring driving voltage to the organic light emitting diode 130, and a capping layer 140 for protecting the organic light emitting diode 130 or enhancing light output efficiency.

The substrate 110 supports and protects a variety of components of the organic light emitting display device 100. The substrate 110 can be made of an insulation material, e.g., a material having flexibility such as a glass or polyimide-based material. In the case where the organic light emitting display device 100 is a flexible organic light emitting display device 100, the organic light emitting display device 100 can be made of a flexible material such as plastic and the like. Additionally, in the case where an organic light emitting diode 130 useful to embody flexibility is applied to a lighting device for a vehicle or a display device for a vehicle, the lighting device for a vehicle or the display device for a vehicle can be designed in various ways and freely in accordance with the structure and exterior shape of a vehicle.

Additionally, the organic light emitting display device 100 according to one or more embodiments of the present disclosure can be applied to a TV, a mobile device, a tablet PC, a monitor, a laptop computer, a display device comprising a display device for a vehicle and the like, and the like. Alternatively, the organic light emitting display device 100 according to one or more embodiments of the present disclosure can also be applied to a wearable display device, a foldable display device, a rollable display device and the like.

The thin film transistor 120 is disposed on the substrate 110. For example, each of the red, blue, first green and second green sub pixels SPR, SPB, SPG1, SPG2 can comprise a driving thin film transistor connecting to an anode 131 of the organic light emitting diode 130, a switching thin film transistor for driving the organic light emitting diode 130, a capacitor and the like.

A planarization layer is disposed on the thin film transistor 120. The planarization layer, as a layer planarizing the upper portion of the substrate 110, can be formed of an organic insulation material to cover a step of the upper portion of the substrate 110. The planarization layer comprises a contact hole for electrically connecting the anode 131 of each of the red, blue, first green and second green sub pixels SPR, SPB, SPG1, SPG2 with the thin film transistor 120.

On the planarization layer, the organic light emitting diode 130 is disposed in response to each of the red, blue, first green and second green sub pixels SPR, SPB, SPG1, SPG2. As illustrated in FIG. 3, one pixel of the organic light emitting display device 100 according to one or more embodiments of the present disclosure comprises red, blue, first green and second green sub pixels SPR, SPB, SPG1, SPG2, and the red sub pixel SPR comprises a red organic light emitting diode, the blue sub pixel SPB comprises a blue organic light emitting diode, the first green sub pixel SPG1 comprises a first green organic light emitting diode, and the second green sub pixel SPG2 comprises a second green organic light emitting diode. The red, blue, first green and second green organic light emitting diodes 130 are disposed on the planarization layer, and respectively comprise an anode 131, an intermediate layer IL and a cathode 135.

The anode 131 is disposed on the planarization layer separately for each of the sub pixels SPR, SPB, SPG1, SPG2. The anode 131 is an electrode configured to provide holes to an organic emission layer out of the intermediate layer IL. The anode 131 can be made of a transparent conductive transparent material of high work function. Herein, the transparent conductive material can comprise indium tin oxide (ITO), indium zinc oxide (IZO), and indium tin zinc oxide (ITZO). The anode 131 electrically connects to the thin film transistor 120 through the contact hole formed at the planarization layer.

The cathode 135 is disposed on the anode 131. The cathode 135 as an electrode providing electrons can be made of a metallic material of relatively low work function, e.g., silver (Ag), titanium (Ti), aluminum (Al), molybdenum (Mo), an alloy (Ag:Mg) of silver (Ag) and magnesium (Mg) or magnesium (Mg) and lithium fluoride (Mg:LiF) and the like. The cathode 135 can be comprised of at least two or more layers. Additionally, in the case where the cathode 135 is made of an alloy (Ag:Mg) of silver (Ag) and magnesium (Mg), the content of silver (Ag) can be greater than the content of magnesium (Mg), to reduce the resistance of the cathode 135. Referring to FIG. 3, the cathode 135 disposed in each of the sub pixels SPR, SPB, SPG1, SPG2 separates for each of the sub pixels SPR, SPB, SPG1, SPG2, but the cathode 135 disposed in each of the sub pixels SPR, SPB, SPG1, SPG2 can connect to each other and be formed commonly.

The intermediate layer IL is disposed between the anode 131 and the cathode 135. The intermediate layer IL is a layer that comprises a plurality of emission parts 132, 134 and is made of an organic material. Referring to FIG. 3, the organic light emitting display device 100 according to one or more embodiments of the present disclosure has a stack structure where the plurality of emission parts 132, 134 is stacked in one sub pixel. Specifically, each of the sub pixels SPR, SPB, SPG1, SPG2 can have a two-stack structure where a first emission part 132 comprising a first organic emission layer and a second emission part 134 comprising a second organic emission layer are included.

The intermediate layer IL constituting the red, blue, first green and second green organic light emitting diodes 130 comprises a first emission part 132, a charge generation layer 133, and a second emission part 134, respectively.

The first emission part 132 is disposed on the anode 131. The first emission part 132 can comprise a hole injection layer HIL, a first hole transport layer HTL1, a first organic emission layer EML1 and a first electron transport layer ETL1.

The hole injection layer HIL injects holes from the anode 131 into the organic emission layer smoothly. The hole injection layer (HIL) can be commonly formed at the red, blue, first green and second green sub pixels SPR, SPB, SPG1, SPG2. The hole injection layer HIL can be selected from a group consisting of NATA, 2T-NATA and NPNPB that are based on arylamine, and F4-TCNQ, PPDN that is a p-doped system, but not limited thereto. The hole injection layer HIL can be omitted depending on the structure or properties of the light emitting diode.

The first hole transport layer HTL1 injects holes from the anode 131 to the first organic emission layer EML1 smoothly. The first hole transport layer HTL1 can be commonly formed at the red, blue, first green and second green sub pixels SPR, SPB, SPG1, SPG2. The first hole transport layer HTL1 can be made of any one or more selected from a group consisting of TPD (N,N′-bis-(3-methylphenyl)-N, N′-bis-(phenyl)-benzidine), PPD, TTBND, FFD, p-dmDPS, TAPC that are based on arylamine, TCTA, PTDATA, TDAPB, TDBA, 4-a, TCTA that are based on starbust aromatic amine, Spiro-TPD, Spiro-mTTB, Spiro-2 that are Spiro and Ladder Type materials, NPD (N, N-dinaphthyl-N, N′-diphenyl benzidine), S-TAD and MTDATA (4,4′,4″-Tris (N-3-methylphenyl-N-phenyl-amino)-triphenylamine), but not limited thereto. The first hole transport layer HTL1 can be constituted by applying two or more layers or two or more materials.

A first auxiliary hole transport layer B′ HTL1 is formed only at the blue sub pixel SPB and the second green sub pixel SPG2 among the red, blue, first green and second green sub pixels SPR, SPB, SPG1, SPG2, on the first hole transport layer HTL1. The first auxiliary hole transport layer B′ HTL1, as an optical auxiliary layer, adjusts a distance between the anode 131 and the cathode 135, i.e., an optical distance of the first organic emission layer EML1. Accordingly, emission efficiency can improve with the micro cavity effect where light emitted from the first organic emission layer EML1 causes interference between the anode 131 and the cathode 135. Additionally, the first auxiliary hole transport layer B′ HTL1 can block electrons in the first organic emission layer EML1 from moving to the first hole transport layer HTL1.

In the case of a first auxiliary hole transport layer B′ HTL1, a highest occupied molecular orbital (HOMO) energy level can be −5.4 to −5.3. Further, in the case of a first auxiliary hole transport layer B′ HTL1, hole mobility can be 5×10⁻⁸ to 5×10⁻⁷ Cm²/Vs. In the case where the HOMO energy level and the hole mobility of the first auxiliary hole transport layer B′ HTL1 satisfy the above ranges, the first auxiliary hole transport layer B′ HTL1 can be disposed together with a second green auxiliary hole transport layer G′ HTL2 so that the emission efficiency and lifespan of the light emitting diode improve.

The first auxiliary hole transport layer B′ HTL1 can comprise spyro fluorene. At this time, the first auxiliary hole transport layer B′ HTL1 can comprise a compound substituted with deuterium. For example, the first auxiliary hole transport layer B′ HTL1 can comprise a compound indicated by chemical formula 1 hereinafter.

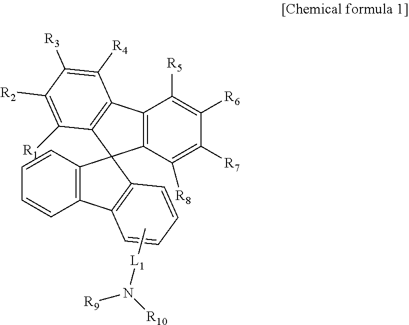

Herein, L₁ is a single bond or selected from a phenyl group and a naphthyl group. R₁ or R₈ is substituted with deuterium. Rg and Rio are selected from a phenyl group, a biphenyl group, a heteroaryl group, a cabazole group, a dibenzofuran group, a dibenzothiophene group that are substituted with deuterium.

The first auxiliary hole transport layer B′ HTL1 blocks a charge from moving to the first hole transport layer HTL1 as well as delivering a hole to a first blue organic emission layer B_EML1 and a second green organic emission layer G EML1-2 from the anode 131. A material constituting the first auxiliary hole transport layer B′ HTL1 Because of the stability of deuterium, charges accumulated on the interfaces of the first auxiliary hole transport layer B′ HTL1, the first blue organic emission layer B_EML1 and the second green organic emission layer G_EML1-2 can be rebounded and moved to the first blue organic emission layer B_EML1 and the second green organic emission layer G_EML1-2 again. Accordingly, a decrease in lifespans, caused by the accumulated charges, can be prevented, and the efficiency of the diode can improve.

For each of the red, blue, first green and second green sub pixels SPR, SPB, SPG1, SPG2, the first organic emission layer EML1 is formed on the first hole transport layer HTL1 and the first auxiliary hole transport layer B′ HTL1. For example, a first red organic emission layer R_EML1 is formed at the red sub pixel SPR, a first blue organic emission layer B_EML1 is formed at the blue sub pixel SPB, a first green organic emission layer G_EML1-1 is formed at the first green sub pixel SPG1, and a second green organic emission layer G_EML1-2 is formed at the second green sub pixel SPG2. Each of the first organic emission layers EML1 can have a different thickness. A material known in the field to which the present disclosure pertains can be used as a material for the first organic emission layer EML1. For example, a material of good fluorescence quantum efficiency or good phosphorescence quantum efficiency can be used as a material for the first organic emission layer EML1.

Specifically, the first organic emission layer EML1 can comprise a phosphorescent dopant material, a hole host material having a hole transport ability and an electron host material having an electron transport ability. Ordinarily, the hole host material having a hole transport ability comprises a carbazole-based host, a triazine-based host, and other hosts. For example, the hole host material comprises x-NPD and TPD as an arylamine-based host, TDAPB and TCTA as a starburst aromatic amine host, and spiro-TAD and OTP-1 as a spiro and ladder-type host.

Further, the electron host material having an electron transport ability comprises a carbazole-based host, a triazine-based host, and other hosts. For example, the electron host material comprises organometallic compounds, sulfone derivatives, oxazole derivatives, triazole derivatives, silole derivatives containing bipyridyl, phenyl benzimidazole containing compounds, and pyrene derivatives. Additionally, the electron mobility of the electron host material having an electron transport ability can have a value of 10-3 to 10-6 Cm²/Vs.

Specifically, the first red organic emission layer R_EML1 can comprise a host material comprising carbazole biphenyl (CBP) or mCP(1,3-bis(carbazol-9-yl) as a specific example of the material for the first organic emission layer EML1, and be made of a phosphorescent material comprising a dopant comprising one or more selected from a group consisting of PIQIr(acac)(bis(1-phenylisoquinoline) acetylacetonate iridium), PQIr(acac)(bis(1-phenylquinoline) acetylacetonate iridium), BtP2Ir(acac), PQIr(tris(1-phenylquinoline) iridium) and PtOEP(octaethylporphyrin platinum), and on the contrary, be made of a fluorescent material comprising PBD:Eu(DBM)3(Phen) or perylene, but not limited thereto.

The first blue organic emission layer B_EML1 can comprise a host material comprising CBP or mCP, and be made of a phosphorescent material comprising a dopant material comprising (4,6-F2ppy)2Irpic, (F2ppy)2Ir(tmd) and Ir(dfppz)3, and on the contrary, be made of a fluorescent material comprising any one selected from a group consisting of spiro-DPVBi, spiro-6P, distill benzene (DSB), distrylarylene (DSA), PFO-based polymer and PPV-based polymer, but not limited thereto.

The first green organic emission layer G_EML1-1 and the second green organic emission layer G_EML1-2 can comprise a host material comprising CBP or mCP, be made of a phosphorescent material comprising a dopant material comprising Ir (ppy)3(fac tris(2-phenylpyridine) iridium), Ir(ppy)2(acac) and Ir(mpyp)3, and on the contrary, be made of a fluorescent material comprising Alq3(tris(8-hydroxyquinolino)aluminum), but not limited thereto. In the case of an organic light emitting display device 100 according to one or more embodiments of the present disclosure, the first green organic emission layer G_EML1-1 and the second green organic emission layer G_EML1-2 can be formed of the same material.

The first electron transport layer ETL1 is disposed on the first organic emission layer EML1. The first electron transport layer ETL1 smooths the transport of an electron to the first organic emission layer EML1 from the charge generation layer 133. The first electron transport layer ETL1 can be commonly formed at the red, blue, first green and second green sub pixels SPR, SPB, SPG1, SPG2. On the contrary, the first electron transport layers ETL1 of the red, blue, first green and second green sub pixels SPR, SPB, SPG1, SPG2 can separate from each other. The first electron transport layer ETL1 can be made of any one or more selected from a group consisting of Alq3 (tris(8-hydroxyquinolino)aluminum), PBD, TAZ, spiro-PBD, BAlq and SAlq, but not limited thereto.

The charge generation layer (CGL) 133 is disposed between the first emission part 132 and the second emission part 134. The charge generation layer 133 adjusts a charge balance of the first organic emission layer EML1 of the first emission part 132 and the second organic emission layer EML2 of the second emission part 134. The charge generation layer 133 can comprise an N-type charge generation layer N-CGL and a P-type charge generation layer P-CGL. The N-type charge generation layer N-CGL injects an electron to the first emission part 132. The N-type charge generation layer N-CGL can comprise an N-type dopant and an N-type host material. The P-type charge generation layer P-CGL injects a hole to the second emission part 134. The P-type charge generation layer P-CGL is disposed on the N-type charge generation layer N-CGL and structured to be bonded to the N-type charge generation layer N-CGL.

The second emission part 134 is disposed on the charge generation layer 133. The second emission part 134 comprises a second hole transport layer HTL2, a second auxiliary hole transport layer R′ HTL2, G′ HTL2, B′ HTL2, a second organic emission layer EML2, a second electron transport layer ETL2 and an electron injection layer EIL.

The second hole transport layer HTL2 injects a hole from the charge generation layer 133 to the second organic emission layer EML2 smoothly. The second hole transport layer HTL2 can be commonly formed at the red, blue, first green and second green sub pixels SPR, SPB, SPG1, SPG2. The second hole transport layer HTL2 can be made of the same material as the first hole transport layer HTL1, and perform the same function as the first hole transport layer HTL1. Accordingly, their common features are not described.

The second auxiliary hole transport layer R′ HTL2, G′ HTL2, B′ HTL2 is disposed on the second hole transport layer HTL2. The second auxiliary hole transport layer R′ HTL2, G′ HTL2, B′ HTL2 as an optical auxiliary layer adjusts a distance between the anode 131 and the cathode 135. Accordingly, emission efficiency can improve with the micro cavity effect where light emitted from the second organic emission layer EML2 causes interference between the anode 131 and the cathode 135. Additionally, the second auxiliary hole transport layer R′ HTL2, G′ HTL2, B′ HTL2 can block electrons in the second organic emission layer EML2 from moving to the second hole transport layer HTL2.

The second auxiliary hole transport layer R′ HTL2, G′ HTL2, B′ HTL2 can be formed at the red, blue, first green and second green sub pixels SPR, SPB, SPG1, SPG2. Specifically, the second auxiliary hole transport layer R′ HTL2, G′ HTL2, B′ HTL2 comprises a second red auxiliary hole transport layer R′ HTL2 disposed at the red sub pixel SPR, a second blue auxiliary hole transport layer B′ HTL2 disposed at the blue sub pixel SPB, and a second green auxiliary hole transport layer G′ HTL2 disposed at the first green sub pixel SPG1. At this time, the second blue auxiliary hole transport layer B′ HTL2 and the second green auxiliary hole transport layer G′ HTL2 are disposed at the second green sub pixel SPG2.

Since the second red auxiliary hole transport layer R′ HTL2 adjusts an optical distance required for emitting red light at the second emission part 134, the thickness of the second red auxiliary hole transport layer R′ HTL2 can be adjusted depending on a wavelength of light emitting from the second red organic emission layer R_EML2. At this time, the thickness of the second red auxiliary hole transport layer R′ HTL2 of the red sub pixel SPR can be greater than the thickness of the second green auxiliary hole transport layer G′ HTL2 of the first green sub pixel SPG1 and the thickness of the second blue auxiliary hole transport layer B′ HTL2 of the blue sub pixel SPB, but not limited thereto.

Since the second green auxiliary hole transport layer G′ HTL2 adjusts an optical distance required for emitting green light at the second emission part 134, the thickness of the second green auxiliary hole transport layer G′ HTL2 is adjusted depending on a wavelength of light emitting from the second green organic emission layer G_EML1-2.

A highest occupied molecular orbital (HOMO) energy level of the second green auxiliary hole transport layer G′ HTL2 can be −5.1 to −5.3 or −5.1 to −5.2. Additionally, the hole mobility of the second green auxiliary hole transport layer G′ HTL2 can be 10-5 to 10-3 Cm²/Vs. In the case where the HOMO energy level and hole mobility of the second green auxiliary hole transport layer G′ HTL2 satisfy the above range, the second green auxiliary hole transport layer G′ HTL2 can be disposed together with the blue auxiliary hole transport layer B′ HTL2 so that the emission efficiency and lifespan of the light emitting diode improve.

Since the second blue auxiliary hole transport layer B′ HTL2 adjusts an optical distance required for emitting blue light at the second emission part 134, the thickness of the second blue auxiliary hole transport layer B′ HTL2 is adjusted depending on a wavelength of light emitting from the second blue organic emission layer B_EML2. Further, the second blue auxiliary hole transport layer B′ HTL2 can block an electron in the second organic emission layer B_EML2 of the blue sub pixel SPB from moving to the second hole transport layer HTL2. The second blue auxiliary hole transport layer B′ HTL2 can be made of the same material as the first auxiliary hole transport layer B′ HTL1, and perform the same function as the first auxiliary hole transport layer B′ HTL1. Accordingly, their common features are not described. In the case of a second blue auxiliary hole transport layer B′ HTL2, a HOMO energy level can be −5.4 to −5.3. In addition, hole mobility of the second blue auxiliary hole transport layer B′ HTL2 can be 5×10⁻⁸ to 5×10⁻⁷ Cm²/Vs. At this time, the second blue auxiliary hole transport layer B′ HTL2 can have a HOMO energy level greater than that of the second green auxiliary hole transport layer G′ HTL2, and have hole mobility less than that of the second green auxiliary hole transport layer G′ HTL2. In the case where the HOMO energy level and hole mobility of the second blue auxiliary hole transport layer B′ HTL2 satisfy the above ranges, the second blue auxiliary hole transport layer B′ HTL2 can be disposed together with the second green auxiliary hole transport layer G′ HTL2 so that the emission efficiency and lifespan of the light emitting diode improve.

Further, the second green auxiliary hole transport layer G′ HTL2 disposed at the first green sub pixel SPG1, and the second blue auxiliary hole transport layer B′ HTL2 disposed at the blue sub pixel SPB are disposed at the second green sub pixel SPG2. For example, the second green auxiliary hole transport layer G′ HTL2 and the second blue auxiliary hole transport layer B′ HTL2 are consecutively stacked between the second hole transport layer HTL2 and a fourth green organic emission layer G_EML2-2. The second green auxiliary hole transport layer G′ HTL2 adjusts an optical distance requiring for emitting green light at the second emission part 134 of the second green sub pixel SPG2. Additionally, the second blue auxiliary hole transport layer B′ HTL2 can block an electron in the fourth green organic emission layer G_EML2-2 of the blue sub pixel SPB from moving to the second hole transport layer HTL2. The thickness of the second green auxiliary hole transport layer G′ HTL2, and the thickness of the second blue auxiliary hole transport layer B′ HTL2 can respectively be 200 Å to 500 Å, and 20 Å to 70 Å, but not limited thereto.

Since the second green sub pixel SPG2 further comprises a second blue auxiliary hole transport layer B′ HTL2 between the second hole transport layer HTL2 and the fourth green organic emission layer G_EML2-2, compared to the first green sub pixel SPG1, an optical distance of the fourth green organic emission layer G_EML2-2 of the second green sub pixel SPG2 differs from an optical distance of a third green organic emission layer G_EML2-1 of the first green sub pixel SPG1. Accordingly, the second green sub pixel SPG2 has emission properties different from those of the first green sub pixel SPG1. For example, the second green sub pixel SPG2 and the first green sub pixel SPG1 have different emission efficiency, a different driving voltage and a different luminance property.

Specifically, since the second green sub pixel SPG2 comprises the second blue auxiliary hole transport layer B′ HTL2 having a function of blocking an electron, under the fourth green organic emission layer G_EML2-2 of the second emission part 134, an electron in the fourth green organic emission layer G_EML2-2 of the second green sub pixel SPG2 can be blocked from moving to the second hole transport layer HTL2, preventing deterioration in the lifespan of the organic light emitting diode 130 and improving emission efficiency.

For each of the red, blue, first green and second green sub pixels SPR, SPB, SPG1, SPG2, the second organic emission layer EML2 is formed on the first auxiliary hole transport layer B′ HTL1. For example, the second red organic emission layer R_EML2 is formed at the red sub pixel SPR, the second blue organic emission layer B_EML2 is formed at the blue sub pixel SPB, the third green organic emission layer G_EML2-1 is formed at the first green sub pixel SPG1, and the fourth green emission layer G_EML2-2 is formed at the second green sub pixel SPG2. Each of the second organic emission layers EML2 can have a different thickness. The second organic emission layers EML2 can be made of the same material as the first organic emission layers EML1 and perform the same function as the first organic emission layers EML1. Accordingly, their common features are not described.

The second electron transport layer ETL2 is disposed on the second organic emission layer EML2. The second electron transport layer ETL2 smooths the transport of an electron to the second organic emission layer EML2 from the cathode 135. The second electron transport layer ETL2 can be formed at the red, blue, first green and second green sub pixels SPR, SPB, SPG1, SPG2.

The second electron transport layer ETL2 can be made of the same material as the first electron transport layer ETL1 and perform the same function as the first electron transport layer ETL1. Accordingly, their common features are not described.

The electron injection layer EIL is disposed on the second electron transport layer ETL2. The electron injection layer EIL smooths the injection of an electron to a plurality of organic layers OL from the cathode 135. The electron injection layer EIL, for example, can be made of a material comprising any one or more of LiF, Al, MOO₃, LiQ (lithium quinolate), Alq3 (tris(8-hydroxyquinolino)aluminum), PBD, TAZ, spiro-PBD, BAlq or SAlq, but not limited thereto.

The capping layer 140 is formed on the cathode 135. The capping layer 140 is to protect the organic light emitting diode 130 and increase a light extraction effect, and the capping layer 140 can be made of any one of a first hole transport layer HTL1, a first electron transport layer ETL1 and a host material of an organic emission layer. Additionally, the capping layer 140 can be omitted. Further, the thickness of the capping layer 140 can be 60 nm to 90 nm.

In the case of an organic light emitting display device according to one or more embodiments of the present disclosure, two green sub pixels having a different optical property are included in one pixel. The organic light emitting display device according to one or more embodiments of the present disclosure comprises red, blue, first green and second green sub pixels, and compared to the first green sub pixel, the second green sub pixel includes an additional auxiliary hole transport layer so that the entire height of the diode and the optical area of the organic emission layer are changed. Thus, the second green sub pixel and the first green sub pixel have a different optical property.

Specifically, each of the red, blue, first green and second green sub pixels comprises a light emitting diode of a two-stack structure comprising a first emission part and a second emission part. A first auxiliary hole transport layer is disposed at the first emission parts of the blue sub pixel and the second green sub pixel to smooth the injection of a hole to the organic emission layer and block an electron from going over to the hole transport layer. At the same time, the second green auxiliary hole transport layer disposed at the second emission part of the first green sub pixel, and the second blue auxiliary hole transport layer disposed at the second emission part of the blue sub pixel are disposed at the second emission part of the second green sub pixel, blocking an electron from coming over from the organic emission layer as well as adjusting an optical distance. Thus, the second green sub pixel can secure emission efficiency and luminance greater than those of the first green sub pixel, and exhibit an emission property leading to a reduction in driving voltage.

The green sub pixel ordinarily shows rising and falling delay properties significantly at a time of turn-on and turn-off, unintended emission of light or an after image can be caused by a remaining charge at a time when the green sub pixel operates. This is highlighted at a time of low-gradation driving. However, in the organic light emitting display device according to one or more embodiments of the present disclosure, since the second green sub pixel having greater emission properties than the first green sub pixel together with the first green sub pixel are disposed at the same time, the second green sub pixel of excellent light emission emits light first at a time of low-gradation driving, resolving the problem at a time of low-gradation driving.

Furthermore, in the case of a light emitting diode using a microcavity effect, a light path on the front surface and a light path on the lateral surface can differ, so that the wavelength of light, which causes resonance, changes. Accordingly, on the lateral surface having a large viewing angle, rather than the front surface, the light path is elongated relatively, and the wavelength of resonated light is shifted to a short wavelength, and luminance deteriorates. In particular, in the case where the green sub pixel is designed to have a less emission surface area than those of the red sub pixel and the blue sub pixel for high emission luminance, deterioration in luminance can be highlighted further based on a change in the viewing angle of the green sub pixel. However, in the organic light emitting display device according to one or more embodiments of the present disclosure, since the first green sub pixel and the second green sub pixel having different optical properties are disposed at the same time, deterioration in luminance based on a viewing angle can be resolved.

In the case where the dopant of the emission layer is used in a different way to form two sub pixels having a different emission property, the number of processes increases. However, in the organic light emitting display device according to one or more embodiments of the present disclosure, since the first hole auxiliary transport layer and the second hole auxiliary transport layer disposed at the blue sub pixel are formed at the same time at the second green sub pixel, the light emitting diode of the first green sub pixel and the second green sub pixel having a different emission property can be formed without adding a separate process.

For identical green sub pixels to emit light of a different emission property, two identical green sub pixels need to be driven separately. To this end, additional lines and drivers are required, complicating a manufacturing process and a driving method. However, in the organic light emitting display device according to one or more embodiments of the present disclosure, even in the case where the first and second green light emitting diodes having a different emission property are used to drive the first green sub pixel and the second green sub pixel at the same time, the second green sub pixel emits light earlier than the first green sub pixel, so that a low-gradation afterimage is readily resolved.

Further, in the organic light emitting display device according to one or more embodiments of the present disclosure, since the emission efficiency of the second green sub pixel is greater than that of the first green sub pixel, the emission surface area of the second green sub pixel can be less than that of the first green sub pixel. As the emission surface area of the second green sub pixel decreases, the emission surface area of another sub pixel, e.g., the emission surface area of the blue sub pixel can increase, thereby improving the lifespan of the entire display device. For example, unlike a conventional pixel arrangement structure, the emission surface area of the blue sub pixel can increase to 5% or 10%.

Hereinafter, effects produced based on the configuration of an adhesive layer are described specifically with reference to embodiments of the present disclosure and comparative examples. However, embodiments of the present disclosure hereinafter are provided as examples, and are not intended to limit the scope of the present disclosure.

### Experimental Example 1

The performance of the diode was estimated in the absence and presence of the second green auxiliary hole transport layer of the second green sub pixel.

In Embodiment 1 of the present disclosure as an organic light emitting display device illustrated in FIG. 3, a first emission part of the second green sub pixel comprises a first auxiliary hole transport layer (B′ HTL1; HOMO energy level: −5.33; hole mobility: 1.0×10⁻⁷ Cm²/Vs) of a thickness of 50 Å, and a second emission part of the second green sub pixel comprises a second green auxiliary hole transport layer (G′ HTL2; HOMO energy level: −5.13; hole mobility: 1.3×10⁻⁴ Cm²/Vs) of a thickness of 300 Å and a second blue auxiliary hole transport layer (B′ HTL2; HOMO energy level: −5.33; hole mobility: 1.0×10⁻⁷ Cm²/Vs) of a thickness of 50 Å.

Comparative example 1 has the same structure as Embodiment 1 except that Comparative example does not include the first auxiliary hole transport layer and the second blue auxiliary hole transport layer.

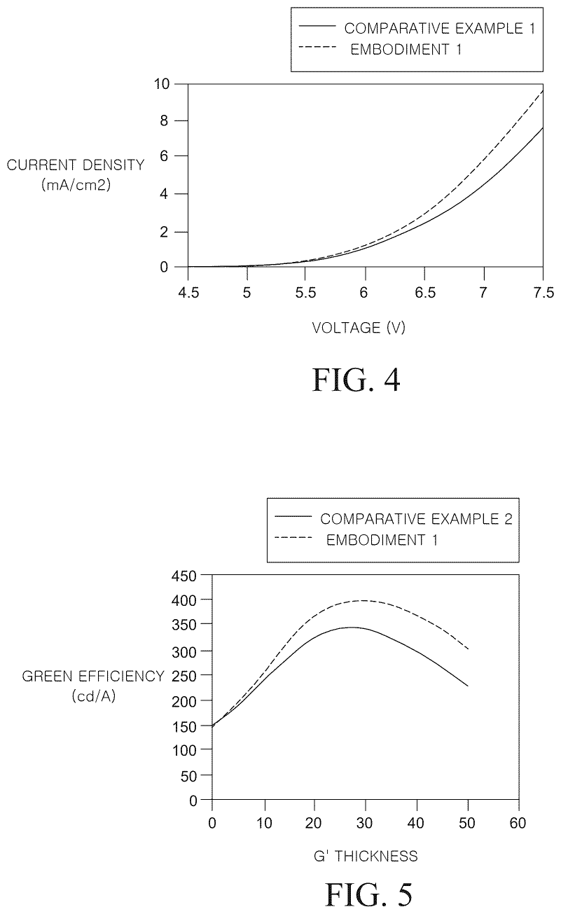

In FIG. 4, current density properties are compared based on a driving voltage of the green sub pixel in Comparative example 1 and Embodiment 1. FIG. 4 is a graph of current density properties based on driving voltage of the green sub pixel of Comparative example 1 and Embodiment 1 of the present disclosure.

Referring to FIG. 4, in the case where the first auxiliary hole transport layer and the second blue auxiliary hole transport layer functioning as an electron blocking layer are disposed respectively at the first emission part and the second emission part of the second green sub pixel, current density can increase, and driving voltage can decrease.

In Table 1 below, driving voltage V, emission efficiency cd/A, and the lifespan of the diode in Embodiment 1 and Comparative example 1 were measured, and then a change in the driving voltage, the efficiency and the lifespan in Embodiment 1 was displayed with respect to Comparative example 1.

TABLE 1

| | Change in | | |
|---|---|---|---|
| | driving | Change in | Change in |
| | voltage | efficiency | lifespan |
| Comparative | — | — | — |
| example 1 | | | |
| Embodiment 1 | Decrease of | Increase of | Increase of |
| | 0.08 V | 3° | 26% |

Referring to Table 1, the driving voltage in Embodiment 1 is decreased compared to Comparative example 1, while the emission efficiency and the lifespan of the diode in Embodiment 1 of the present disclosure are increased compared to Comparative example 1.

### Experimental Example 2

The emission efficiency was estimated based on a varying position and thickness of the second green auxiliary hole transport layer of the second green sub pixel.

Comparative example 2 has the same structure as Embodiment 1 of the present disclosure except that the second green auxiliary hole transport layer (G′ HTL2; HOMO energy level: −5.13; hole mobility: 1.3×10⁻⁴ Cm²/Vs) is disposed on the first hole transport layer HTL1 of the first emission part 132 rather than the second emission part 134.

In Table 2 below, the emission efficiency was estimated based on a varying thickness of the second green auxiliary hole transport layer of the second green sub pixel disposed respectively at the second emission part or the first emission part in Embodiment 1 of the present disclosure and Comparative example 2.

TABLE 2

| Thickness (nm) of | Emission | | Change in |
|---|---|---|---|
| second green | efficiency (cd/A) | | emission |
| auxiliary hole | Comparative | | efficiency |
| transport layer | example 2 | Embodiment 1 | (%) |
| 0 | 144.71 | 144.71 | 0 |
| 5 | 186.0674 | 194.1929 | 4.3670 |
| 10 | 234.6899 | 255.4491 | 8.8454 |
| 15 | 283.6394 | 318.4429 | 12.2703 |
| 20 | 322.0576 | 368.1828 | 14.3220 |
| 25 | 341.2553 | 395.1927 | 15.8056 |
| 30 | 339.9934 | 400.6084 | 17.8283 |
| 35 | 323.2714 | 390.8436 | 20.9026 |
| 40 | 297.1411 | 370.4922 | 24.6856 |
| 45 | 265.1687 | 341.2437 | 28.6893 |
| 50 | 229.0963 | 304.507 | 32.9166 |

FIG. 5 is a graph showing light efficiency properties based on the thickness of the second green auxiliary hole transport layer of the second green sub pixel in Embodiment 1 of the present disclosure and Comparative example 2. For example, FIG. 5 is a graph of Table 2 above. Referring to Table 2, in the case where the thickness of the second green auxiliary hole transport layer of the second green sub pixel is 20-40 nm, the emission efficiency improves significantly.

Referring to FIG. 5, in the case where the second green auxiliary hole transport layer is disposed at the second emission part rather than the first emission part, the emission efficiency improves by about 17%, based on results that are measured at a thickness of the green auxiliary hole transport layer, which secures maximum efficiency.

The example embodiments of the present disclosure can also be described as follows:

According to an aspect of the present disclosure, there is provided an organic light emitting display device. The organic light emitting display device comprises a substrate on which a red sub pixel, a blue sub pixel, a first green sub pixel and a second green sub pixel are disposed; an anode disposed separately at each of the red, blue, first green and second green sub pixels; a first hole transport layer disposed on the anode; a first auxiliary hole transport layer disposed on the first hole transport layer, at the blue sub pixel and the second green sub pixel; a first red organic emission layer, a first blue organic emission layer, a first green organic emission layer and a second green organic emission layer disposed respectively at the red, blue, first green and second green sub pixels; a charge generation layer disposed on the red, blue, first green and second green organic emission layers; a second auxiliary hole transport layer disposed on the charge generation layer; a second red organic emission layer, a second blue organic emission layer, a third green organic emission layer and a fourth green organic emission layer disposed on the second auxiliary hole transport layer, at each of the red, blue, first green and second green sub pixels; an electron transport layer disposed on the second red, second blue, third green and fourth green organic emission layer; and a cathode disposed on the electron transport layer. The second auxiliary hole transport layer comprises a second green auxiliary hole transport layer and a second blue auxiliary hole transport layer disposed at the second green sub pixel.

The second blue auxiliary hole transport layer can be disposed on the second green auxiliary hole transport layer, at the second green sub pixel.

The second auxiliary hole transport layer can further comprise a second red auxiliary hole transport layer disposed at the red sub pixel, the second green auxiliary hole transport layer can be disposed at the first green sub pixel and the second green sub pixel, and the second blue auxiliary hole transport layer can be disposed at the blue sub pixel and the second green sub pixel.

The first auxiliary hole transport layer and the second blue auxiliary hole transport layer can be made of the same material.

The first auxiliary hole transport layer and the second blue auxiliary hole transport layer can comprise a spyro fluorene compound at least part of which is substituted with deuterium.

The second blue auxiliary hole transport layer can have a greater HOMO energy level and less hole mobility than the second green auxiliary hole transport layer.

An optical distance of the second green organic emission layer of the second green sub pixel can be greater than an optical distance of the first green organic emission layer of the first green sub pixel, and an optical distance of the fourth green organic emission layer of the second green sub pixel can be greater than an optical distance of the third green organic emission layer of the first green sub pixel.

An emission surface area of the second green sub pixel can be greater than an emission surface area of the first green sub pixel.

Emission efficiency of the second green sub pixel can be greater than emission efficiency of the first green sub pixel.

The present disclosure being thus described, it will be obvious that the same may be varied in many ways. Such variations are not to be regarded as a departure from the spirit and scope of the present disclosure, and all such modifications as would be obvious to one skilled in the art are intended to be included within the scope of the following claims.

What is claimed is:

1. An organic light emitting display device, comprising:
a substrate on which a red sub pixel, a blue sub pixel, a first green sub pixel and a second green sub pixel are disposed;
an anode disposed separately at each of the red, blue, first green and second green sub pixels;
a first hole transport layer disposed on the anode;
a first auxiliary hole transport layer disposed on the first hole transport layer, at the blue sub pixel and the second green sub pixel;
a first red organic emission layer, a first blue organic emission layer, a first green organic emission layer and a second green organic emission layer disposed respectively at the red, blue, first green and second green sub pixels;
a charge generation layer disposed on the red, blue, first green and second green organic emission layers;
a second auxiliary hole transport layer disposed on the charge generation layer;
a second red organic emission layer, a second blue organic emission layer, a third green organic emission layer and a fourth green organic emission layer disposed on the second auxiliary hole transport layer, at each of the red, blue, first green and second green sub pixels;
an electron transport layer disposed on the second red, second blue, third green and fourth green organic emission layer; and
a cathode disposed on the electron transport layer,
wherein the second auxiliary hole transport layer comprises a second green auxiliary hole transport layer and a second blue auxiliary hole transport layer disposed at the second green sub pixel.

2. The organic light emitting display device of claim 1,
wherein the second blue auxiliary hole transport layer is disposed on the second green auxiliary hole transport layer, at the second green sub pixel.

3. The organic light emitting display device of claim 2, wherein the second auxiliary hole transport layer further comprises a second red auxiliary hole transport layer disposed at the red sub pixel,
the second green auxiliary hole transport layer is disposed at the first green sub pixel and the second green sub pixel, and
the second blue auxiliary hole transport layer is disposed at the blue sub pixel and the second green sub pixel.

4. The organic light emitting display device of claim 1, wherein the first auxiliary hole transport layer and the second blue auxiliary hole transport layer include a same material.

5. The organic light emitting display device of claim 1, wherein the first auxiliary hole transport layer and the second blue auxiliary hole transport layer comprise a spyro fluorene compound at least part of which is substituted with deuterium.

6. The organic light emitting display device of claim 1, wherein the second blue auxiliary hole transport layer has a greater highest occupied molecular orbital (HOMO) energy level and a less hole mobility than the second green auxiliary hole transport layer.

7. The organic light emitting display device of claim 1, wherein an optical distance of the second green organic emission layer of the second green sub pixel is greater than an optical distance of the first green organic emission layer of the first green sub pixel, and
an optical distance of the fourth green organic emission layer of the second green sub pixel is greater than an optical distance of the third green organic emission layer of the first green sub pixel.

8. The organic light emitting display device of claim 1, wherein an emission surface area of the second green sub pixel is greater than an emission surface area of the first green sub pixel.

9. The organic light emitting display device of claim 1, wherein an emission efficiency of the second green sub pixel is greater than an emission efficiency of the first green sub pixel.

10. The organic light emitting display device of claim 1, wherein the red sub pixel, the blue sub pixel, the first green sub pixel and the second green sub pixel are arranged in a pentile structure.

11. The organic light emitting display device of claim 1, wherein the thickness of the second red auxiliary hole transport layer is greater than the thickness of the second green auxiliary hole transport layer and the thickness of the second blue auxiliary hole transport layer.

12. The organic light emitting display device of claim 1, further comprising a second hole transport layer disposed on the charge generation layer, wherein the second auxiliary hole transport layer is disposed on the second hole transport layer.

13. The organic light emitting display device of claim 1, further comprising a capping layer disposed on the cathode.

14. An organic light emitting display device, comprising:
a substrate on which a red sub pixel, a blue sub pixel, a first green sub pixel and a second green sub pixel are disposed;
an anode disposed separately at each of the red, blue, first green and second green sub pixels;
a first hole transport layer disposed on the anode;
a first red organic emission layer, a first blue organic emission layer, a first green organic emission layer and a second green organic emission layer disposed respectively at the red, blue, first green and second green sub pixels;
a charge generation layer disposed on the red, blue, first green and second green organic emission layers;
an electron transport layer disposed on the charge generation layer; and
a cathode disposed on the electron transport layer,
wherein the second green sub pixel includes an additional auxiliary hole transport layer compared to the first green sub pixel, the auxiliary hole transport layer includes a first auxiliary hole transport layer disposed between the hole transport layer and the charge generation layer, at the second green sub pixel, and/or a second auxiliary hole transport layer disposed between the charge generation layer and the electron transport layer, at the second green sub pixel, so that the second green sub pixel has greater emission properties than the first green sub pixel.

15. The organic light emitting display device of claim 1, wherein the second green sub pixel has greater emission efficiency and luminance than those of the first green sub pixel.
